(19) United States
(12) Patent Application Publication
(10) Pub. No.: US 2009/0283822 A1
(43) Pub. Date: Nov. 19, 2009

(54) NON-VOLATILE MEMORY STRUCTURE AND METHOD FOR PREPARING THE SAME

(75) Inventors: WAN TENG HSIEH, TAICHUNG COUNTY (TW); I HSUAN LIAO, TAICHUNG COUNTY (TW); SHIH FANG CHEN, HSINCHU COUNTY (TW); TING CHANG CHANG, KAOHSIUNG CITY (TW); PENG BO XI, TAOYUAN COUNTY (TW); WEI REN CHEN, PINGTUNG CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 12/122,150

(22) Filed: May 16, 2008

(51) Int. Cl. H01L 29/792; H01L 21/28

(52) U.S. Cl. 257/325; 438/591; 257/E21.18; 257/E29.309

(57) ABSTRACT

A non-volatile memory structure includes a substrate having two doped regions, a charge-trapping structure positioned substantially between the two doped regions, and a conductive structure positioned on the charge-trapping structure, wherein the charge-trapping structure includes a silicon-oxy-nitride layer and metallic nano-dots embedded in the silicon-oxy-nitride layer. The non-volatile memory structure formed by performing a first thermal oxidation process to form a high-k dielectric layer on a substrate, forming a metal-containing semiconductor layer including silicon or germanium on the high-k dielectric layer, forming a silicon layer on the metal-containing semiconductor layer, and performing a second thermal oxidation process to convert the metal-containing semiconductor layer to a silicon-oxy-nitride layer with embedded metallic nano-dots, wherein at least one of the first thermal oxidation process and the second thermal oxidation process is performed in a nitrogen-containing atmosphere.

### BACKGROUND OF THE INVENTION

(A) Field of the Invention

The present invention relates to a non-volatile memory structure and method for preparing the same, and more particularly, to a non-volatile memory structure with high-density metallic nano-dots and method for preparing the same.

(B) Description of the Related Art

Non-volatile memories such as flash memory have been widely used for data storage in digital products such as laptop computers, personal digital assistants, cell phones, digital cameras, digital recorders, and MP3 players. Non-volatile memory devices that use charge-trapping mechanisms have been widely studied. Advantages of flash memories include non-volatility, i.e., information can be stored in the memory even when power supply is disconnected, and fast erasure speed.

A trapping-type non-volatile memory device such as floating gate flash memory can be manufactured on a semiconductor substrate and generally includes an array of memory cells each having a control gate and a floating gate. Electric charges can be stored in the floating gate, thereby changing the status of the respective memory cell. However, the trapped electric charges in the floating gate may be completely lost if there is a leakage path between the floating gate and another conductive member of the floating gate flash memory.

### SUMMARY OF THE INVENTION

One aspect of the present invention provides a non-volatile memory structure and method for preparing the same.

A non-volatile memory structure according to this aspect of the present invention comprises a substrate having two doped regions, a charge-trapping structure positioned substantially between the two doped regions, and a conductive structure positioned on the charge-trapping structure, wherein the charge-trapping structure includes a silicon-oxy-nitride layer and metallic nano-dots embedded in the silicon-oxy-nitride layer.

A method for preparing a non-volatile memory structure according to this aspect of the present invention comprises the steps of performing a first thermal oxidation process to form a high-k dielectric layer on a substrate, forming a metal-containing semiconductor layer including silicon or germanium on the high-k dielectric layer, forming a silicon layer on the metal-containing semiconductor layer, and performing a second thermal oxidation process to convert the metal-containing semiconductor layer to a silicon-oxy-nitride layer with embedded metallic nano-dots, wherein at least one of the first thermal oxidation process and the second thermal oxidation process is performed in a nitrogen-containing atmosphere.

The metallic nano-dots are isolated from each other by the silicon-oxy-nitride layer, and the charge leakage of one metallic nano-dot will not influence the trapped electric charge of the other metallic nano-dots. Consequently, the electric charges trapped in the metallic nano-dots, serving as discrete floating gates, will not be completely lost even if there is a leakage path between one of the metallic nano-dots and another conductive member of the non-volatile memory structure. In other words, the charge-trapping structure with embedded metallic nano-dots isolated from each other by the silicon-oxy-nitride layer can provide better charge retention endurance than the conventional floating gate made of a single conductive block.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 to FIG. 4 illustrate a method for preparing a non-volatile memory structure according to one embodiment of the present invention;

FIG. 5 and FIG. 6 show the transmission electron microscopy images of the metallic nano-dots according to the present invention and the prior art;

FIG. 7 and FIG. 8 show the size distribution of the metallic nano-dots; and

FIG. 9 and FIG. 10 show the transmission electron microscopy images of the metallic nano-dots according to the present invention and the prior art.

### DETAILED DESCRIPTION OF THE INVENTION

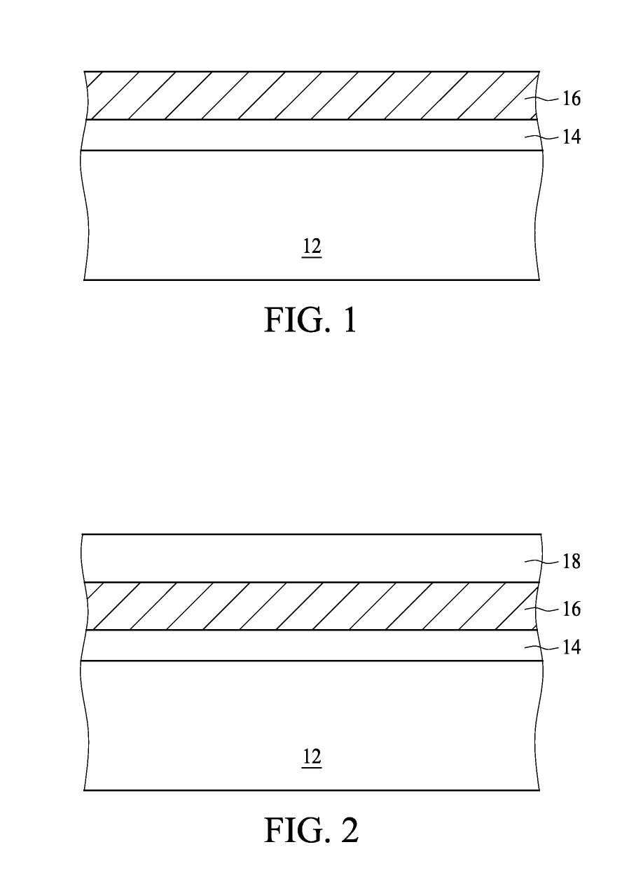

FIG. 1 to FIG. 4 illustrate a method for preparing a non-volatile memory structure 10 according to one embodiment of the present invention. Referring to FIG. 1, a high-k dielectric layer 14 is formed on a silicon substrate 12 by a first thermal oxidation process, and a metal-containing semiconductor layer 16 is then formed on the high-k dielectric layer 14 by a chemical vapor phase deposition process. The high-k dielectric layer 14 is made of high-k material with a dielectric constant higher than the dielectric constant of the silicon, and can be a silicon oxide layer. The metal-containing semiconductor layer 16 may include silicon or germanium, and can be metallic silicide layer such as tungsten silicide (WSiₓ) layer, a cobalt silicide (CoSiₓ) layer, or a titanium silicide (TiSiₓ) layer.

The first thermal oxidation process can be performed at a temperature between 950 and 1200° C. for 20 to 1200 seconds, preferably for 30 to 80 seconds. In particular, the first thermal oxidation process forms the high-k dielectric layer 14, which serves as a tunneling dielectric layer comprising one or more compounds selected from the group of the silicon oxide, aluminum oxide, hafnium oxide, or zirconium oxide. Preferably, the tunneling dielectric layer is positioned on the silicon substrate 12.

In FIG. 2, a silicon layer 18 is formed on the metal-containing semiconductor layer 16 by a chemical vapor phase deposition process. Preferably, the silicon layer 18 is an amorphous silicon layer or a polysilicon layer, and the metal-containing semiconductor layer 16 and the silicon layer 18 are preferably formed by the chemical vapor phase deposition process in the same chamber.

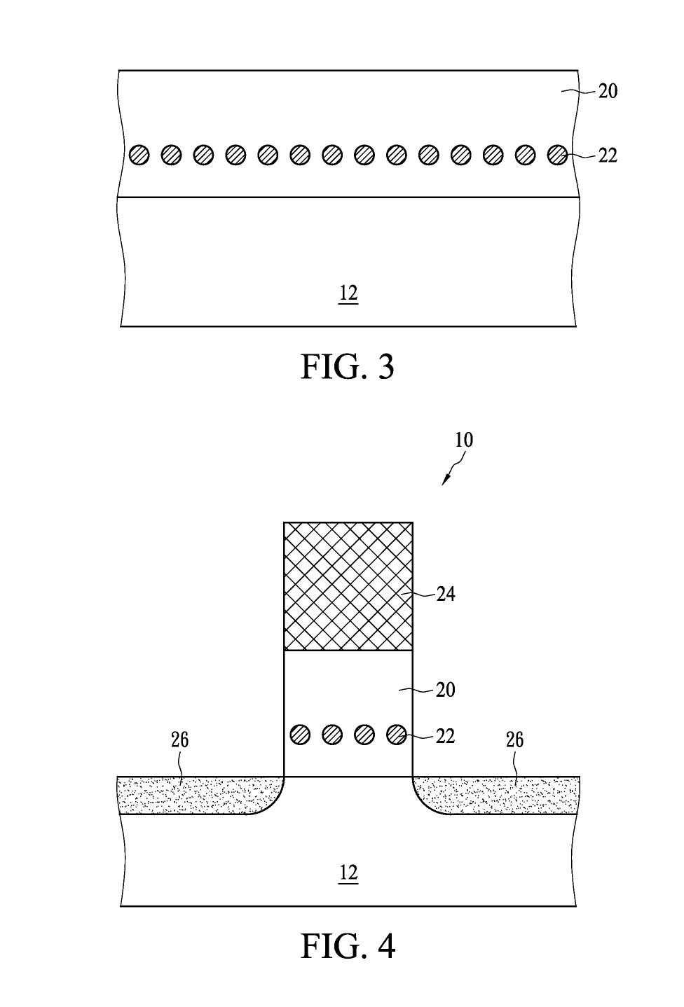

In FIG. 3, a second thermal oxidation process is performed in a nitrogen-containing atmosphere to convert the high-k dielectric layer 14, the metal-containing semiconductor layer 16 and the silicon layer 18 into a silicon-oxy-nitride layer 20 with embedded metallic nano-dots 22. Preferably, the second thermal oxidation process can be performed at a temperature between 950 and 1200° C. for 60 to 200 seconds, preferably for 30 to 80 seconds. The metallic nano-dots 22 may comprise tungsten, cobalt, titanium, gold, or platinum.

In particular, the second thermal oxidation process is performed in the nitrogen-containing atmosphere in a chamber with an amount of nitrogen-containing gas more than 50% based on the volume of the nitrogen-containing atmosphere. The nitrogen-containing atmosphere may include nitric oxide (NO), nitrous oxide (N₂O), or ammonia (NH₃). In addition, the first thermal oxidation process can also be optionally performed in a nitrogen-containing atmosphere.

In FIG. 4, a conductive structure 24 is formed on the silicon-oxy-nitride layer 20 by a deposition process, a photolithographic process and an etching process, and an implanting process is then performed to form two doped regions 26 in the silicon substrate 12 to complete the non-volatile memory structure 10. In particular, the silicon-oxy-nitride layer 20 with embedded metallic nano-dots 22 forms a charge-trapping structure serving as a floating gate, the conductive structure 24 serves as a control gate, and the two doped regions 26 serve as a source/drain of a transistor for the non-volatile memory structure 10. In particular, each of the metallic nano-dots 22 serves as a discrete floating gate isolated from the others by the silicon-oxy-nitride layer 20, and the charge-trapping structure is positioned on the tunneling dielectric layer and between the two doped regions 26.

Table 1 compares the electrical properties of the non-volatile memory structures prepared by using the second thermal oxidation process in the nitrogen-containing atmosphere (Example 1) according to the present invention and in the oxygen atmosphere (Example 2) according to the prior art. The second thermal oxidation process in the Example 1 is performed in the nitrogen-containing (N₂O) atmosphere, and the second thermal oxidation process in the Example 2 is performed in the oxygen (O₂) atmosphere. Obviously, the non-volatile memory structure prepared by using the second thermal oxidation process in the nitrogen-containing atmosphere has a lower decay rate and longer retention time than that prepared in the oxygen atmosphere.

TABLE 1

| | Example 1 | | Example 2 | |
|---|---|---|---|---|
| Dot density | 3.9 × 10¹¹ | | 1.1 × 10¹¹ | |
| Dot size | 4.7 | nm | 6.8-12.2 | nm |
| Window after 1 second | 1.16 | V | 1.65 | V |
| Window after 1000 second | 0.81 | V | 0.71 | V |
| Program Decay Rate | −84.25 | mV/dec | −184.76 | mV/dec |
| between 1 and 1000 second | | | | |
| Program Decay Rate | −21.56 | mV/dec | −28.89 | mV/dec |
| between 300 and 1000 | | | | |
| second | | | | |
| Erase Decay Rate between | −33.61 | mV/dec | −128.48 | mV/dec |
| 300 and 1000 second | | | | |
| Retention 20% time | 7.8 × 10³ | second | 4.88 × 10³ | second |

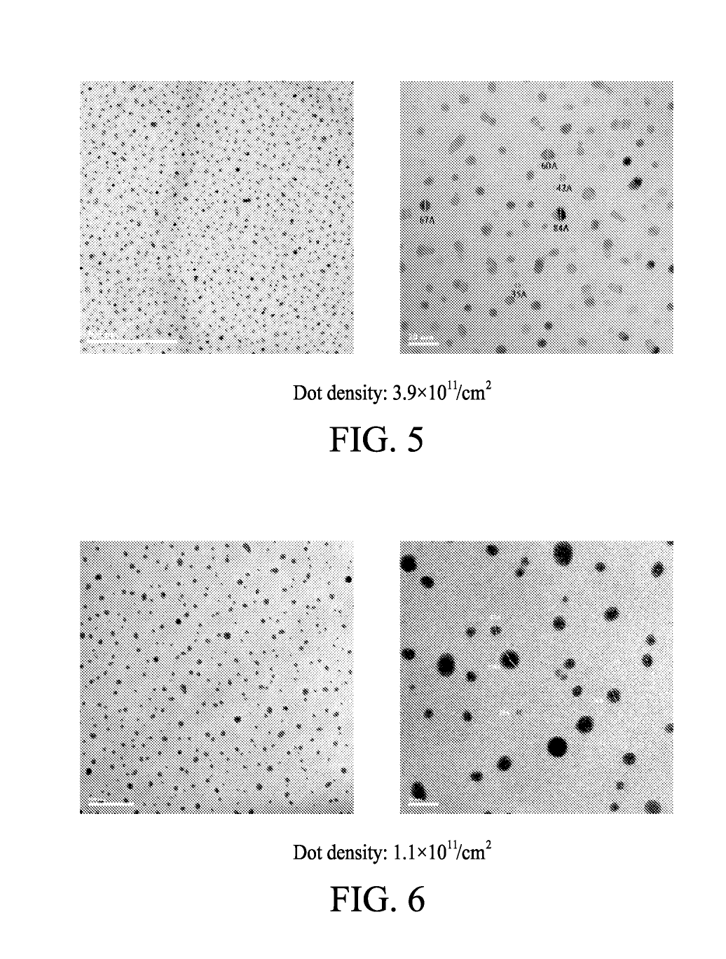

FIG. 5 and FIG. 6 shows the transmission electron microscopy (TEM) images of the metallic nano-dots prepared by using the second thermal oxidation process in the nitrogen-containing atmosphere (Example 1) according to the present invention and in the oxygen atmosphere (Example 2) according to the prior art. The metallic nano-dots prepared by using the second thermal oxidation process in the nitrogen-containing atmosphere according to the present invention have a density of up to 3.9×10¹¹/cm² and a size between 35 and 67 angstrom, while those prepared by the second thermal oxidation process in the oxygen atmosphere according to the prior art have a density of about 1.1×10¹¹/cm² and a size between 28 and 193 angstrom. Obviously, the metallic nano-dots prepared by using the second thermal oxidation process in the nitrogen-containing atmosphere have smaller size and higher density than those prepared in the oxygen atmosphere.

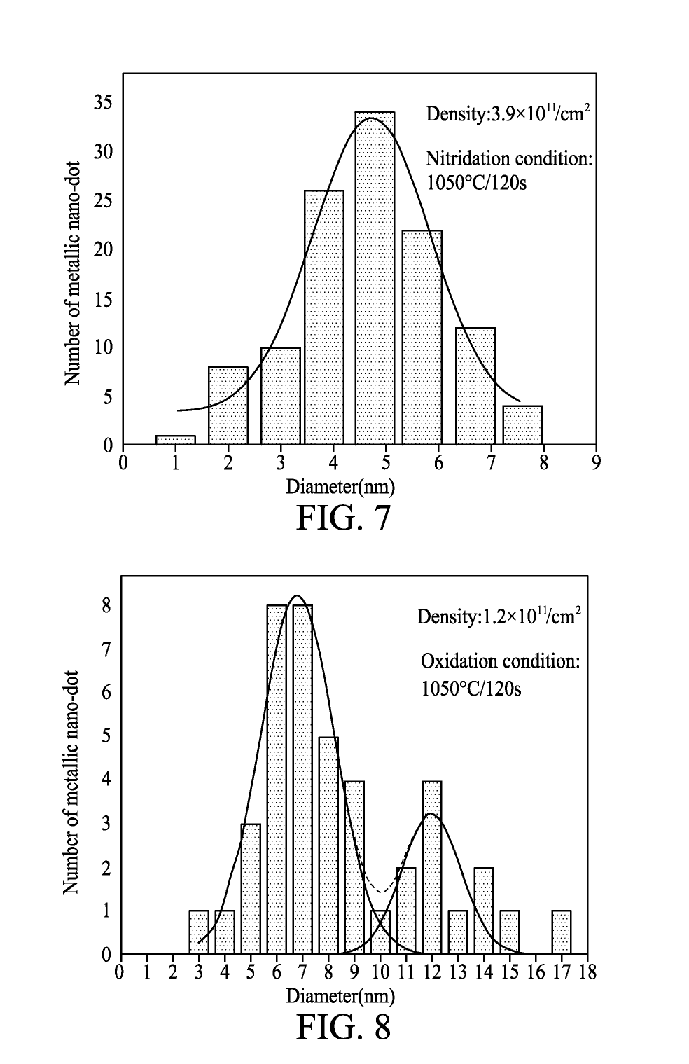

FIG. 7 and FIG. 8 shows the size distribution of the metallic nano-dots prepared by using the second thermal oxidation process in the nitrogen-containing atmosphere (Example 1) according to the present invention and in the oxygen atmosphere (Example 2) according to the prior art. The mean size of the metallic nano-dots prepared by using the second thermal oxidation process in the nitrogen-containing atmosphere according to the present invention is about 4.7 nanometers, while the mean size of the metallic nano-dots prepared in the oxygen atmosphere according to the prior art is between 6.8 and 12.2 nanometer. In other words, the metallic nano-dots prepared by using the second thermal oxidation process in the nitrogen-containing atmosphere have better dot distribution uniformity than those prepared in the oxygen atmosphere.

Table 2 compares the electrical properties of the non-volatile memory structures prepared by using the first thermal oxidation process in the nitrogen-containing atmosphere (example 3) according to the present invention and in the oxygen atmosphere (example 4) according to the prior art. Obviously, the non-volatile memory structure prepared by using the first thermal oxidation process in the nitrogen-containing atmosphere has a lower decay rate and flat band voltage (Vfb) than that prepared in the oxygen atmosphere. In particular, a lower decay rate means higher retention time.

TABLE 2

| | Example 3 | | Example 4 | |
|---|---|---|---|---|
| Window after 1 second | 0.4 | V | 0.69 | V |
| Program Decay Rate | −36.13 | mV/sec | −63.32 | mV/sec |
| Erase Decay Rate | −38.94 | mV/sec | −45.53 | mV/sec |
| Window after 1.0 × 10⁸ | 0.14 | V | 0.24 | V |
| second | | | | |
| Vfb Shift | 0.33 | V | 0.6 | V |

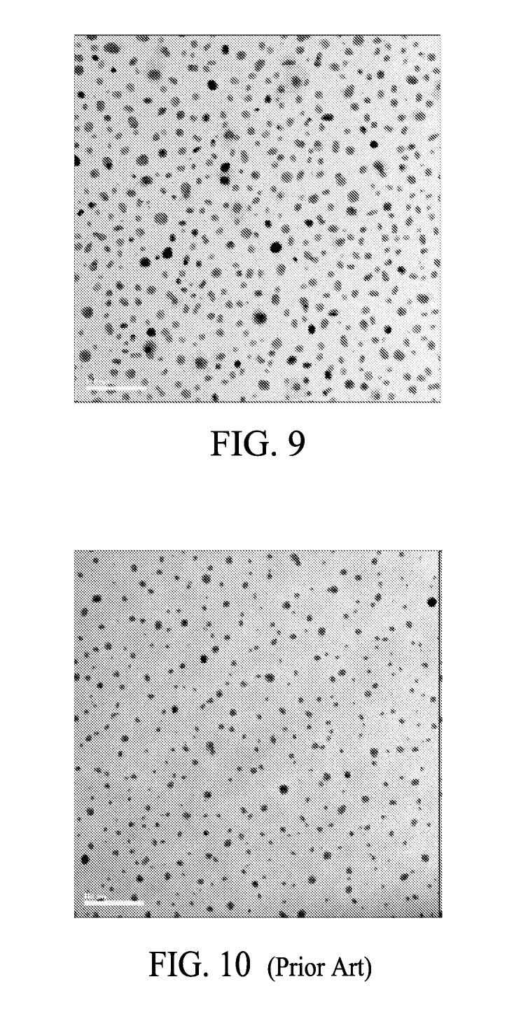

FIG. 9 and FIG. 10 shows the transmission electron microscopy images of the metallic nano-dots prepared by using the first thermal oxidation process in a nitrogen-containing (Example 3) atmosphere according to the present invention and in an oxygen (Example 4) atmosphere according to the prior art. The first thermal oxidation process in the Example 3 is performed in the nitrogen-containing (N₂O) atmosphere at 1050° C. for 120 seconds, and the first thermal oxidation process in the Example 4 is performed in the oxygen (O₂) atmosphere at 1050° C. for 120 seconds. Obviously, the density of the metallic nano-dots prepared by using the first thermal oxidation process in the nitrogen-containing atmosphere according to the present invention is higher than those prepared by using the first thermal oxidation process in the oxygen atmosphere according to the prior art.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A non-volatile memory structure, comprising:
a substrate having two doped regions;
a charge-trapping structure positioned substantially between the two doped regions, and the charge-trapping structure comprising a silicon-oxy-nitride layer and metallic nano-dots embedded in the silicon-oxy-nitride layer; and
a conductive structure positioned on the charge-trapping structure.

2. The non-volatile memory structure of claim 1, wherein the metallic nano-dots comprises tungsten, cobalt, titanium, gold, or platinum.

3. The non-volatile memory structure of claim 1, wherein the two doped regions serve as a source/drain of a transistor.

4. The non-volatile memory structure of claim 1, wherein the charge-trapping structure is formed in a nitrogen-containing atmosphere.

5. The non-volatile memory structure of claim 4, wherein the nitrogen-containing atmosphere is nitric oxide, nitrous oxide, or ammonia.

6. The non-volatile memory structure of claim 4, wherein an amount of nitrogen-containing gas in the nitrogen-containing atmosphere is more than 50% based on the volume of the nitrogen-containing atmosphere.

7. The non-volatile memory structure of claim 1, wherein the metallic nano-dots include material selected from the group of tungsten, cobalt, titanium, gold, platinum and the combination thereof.

8. The non-volatile memory structure of claim 1, wherein the metallic nano-dots are tungsten.

9. A method for preparing a non-volatile memory structure, comprising the steps of:
performing a first thermal oxidation process to form a high-k dielectric layer on a substrate;
forming a metal-containing semiconductor layer on the high-k dielectric layer;
forming a silicon layer on the metal-containing semiconductor layer; and
performing a second thermal oxidation process to convert the metal-containing semiconductor layer to a silicon-oxy-nitride layer with embedded metallic nano-dots, wherein at least one of the first thermal oxidation process and the second thermal oxidation process is performed in a nitrogen-containing atmosphere.

10. The method of claim 9, wherein a tunneling dielectric layer comprising one or more compounds selected from the group of the silicon oxide, aluminum oxide, hafnium oxide, or zirconium oxide.

11. The method of claim 9, wherein the first thermal oxidation process is performed for 20 to 80 seconds in the nitrogen-containing atmosphere.

12. The method of claim 9, wherein the first thermal oxidation process is performed at a temperature between 950 and 1150° C. in the nitrogen-containing atmosphere.

13. The method of claim 9, wherein the second thermal oxidation process is performed for 60 to 200 seconds in the nitrogen-containing atmosphere.

14. The method of claim 9, wherein the second thermal oxidation process is performed at a temperature between 950 and 1150° C. in the nitrogen-containing atmosphere.

15. The method of claim 9, wherein the nitrogen-containing atmosphere is nitric oxide, nitrous oxide, or ammonia.

16. The method of claim 9, wherein an amount of nitrogen-containing gas is more than 50% based on the volume of the nitrogen-containing atmosphere.

17. The method of claim 9, wherein the first thermal oxidation and the second thermal oxidation process are performed in the nitrogen-containing atmosphere.

18. The method of claim 9, wherein the metal-containing semiconductor layer and the silicon layer are formed by a chemical vapor phase deposition process in the same chamber.

19. The method of claim 9, wherein the silicon layer is an amorphous silicon layer or a polysilicon layer.

20. The method of claim 9, wherein the metal-containing semiconductor layer is a metallic silicide layer.

21. The method of claim 20, wherein the metallic silicide layer is a tungsten silicide layer, a cobalt silicide layer, or a titanium silicide layer.

22. The method of claim 9, wherein the metal-containing semiconductor layer includes silicon or germanium.
